(19) United States
(12) Patent Application Publication
(10) Pub. No.: US 2010/0019220 A1
(43) Pub. Date: Jan. 28, 2010

(54) Phase change random access memory device, method of fabricating the same, and method of operating the same

(75) Inventor: Dong-seok Suh, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/458,758

(22) Filed: Jul. 22, 2009

(30) Foreign Application Priority Data
Jul. 25, 2008 (KR) 10-2008-0072955

(51) Int. Cl. H01L 45/00

(52) U.S. Cl. 257/4; 257/E45.002; 365/175

(57) ABSTRACT

Provided are a phase change random access memory (PRAM), a method of fabricating the PRAM, and a method of operating the PRAM. The PRAM may include a gate electrode configured to temporarily increase an electrical resistance of the lower electrode contact layer if a voltage is applied to the gate electrode, and around the lower electrode contact layer between a switching device and a phase change layer. A spacer insulating layer is disposed between the lower electrode contact layer and the gate electrode.

### PRIORITY STATEMENT

This application claims priority under 35 USC §119 to Korean Patent Application No. 10-2008-0072955, filed on Jul. 25, 2008, in the Korean Intellectual Property Office (KIPO), the entire contents of which is incorporated herein by reference.

### BACKGROUND

1. Field

Example embodiments relate to a phase change random access memory (PRAM), a method of fabricating the PRAM, and a method of operating the PRAM.

2. Description of the Related Art

Phase change random access memory devices (PRAM) are memories storing data 0 and 1 using a difference between resistances when a phase change material is in a crystallized status and in an amorphous status. In order to change the phase of the phase change material in PRAM from the crystallized status to the amorphous status, electric current is supplied to PRAM so as to generate Joule heat that melts the phase change material, for example, GST, and the current is referred to as a reset current.

One of the requirements in order to develop a highly integrated PRAM is to reduce the reset current. The reset current may be reduced by adopting a high resistance bottom electrode contact (BEC) using a composition change of the BEC, or adopting a ring-shaped BEC that increases a current density by changing the BEC configuration. According to the above methods, the Joule heat increases, and the reset current may be reduced. However, a set resistance of the PRAM also increases, and thus, a ratio between the reset resistance and the set resistance of the PRAM may be reduced. When the ratio between the reset resistance and the set resistance of the PRAM decreases, a sensing margin is reduced when reading data. Therefore, reliability of the reading operation may be degraded.

### SUMMARY

Example embodiments include a phase change random access memory (PRAM), a reset current of which may be reduced without affecting a set resistance, a method of fabricating the PRAM, and a method of operating the PRAM. Additional aspects will be set forth in part in the description which follows and, in part, will be apparent from the description, or may be learned by practice of example embodiments.

According to example embodiments, a phase change random access memory (PRAM) may include a switching device; a storage node including a phase change layer and a lower electrode contact layer; and a gate electrode configured to temporarily increase an electrical resistance of the lower electrode contact layer if a voltage is applied to the gate electrode.

A spacer insulating layer may be disposed between the lower electrode contact layer and the gate electrode. The gate electrode may be disposed around the lower electrode contact layer, and the gate electrode may be a unit for applying an electrical field to the lower electrode contact layer in a reset programming. The PRAM may further include at least one additional switching device and at least one additional storage node including at least one phase change layer and at least one lower electrode contact layer, and the gate electrode may correspond to the at least one lower electrode contact layer. The lower electrode contact layer may be a layer formed of a material that changes an electrical resistance in the electrical field.

According to example embodiments, a method of fabricating a phase change random access memory (PRAM) may include forming a switching device on a substrate; forming a lower electrode contact layer connected to the switching device; forming a gate electrode that temporarily increases an electrical resistance of the lower electrode contact layer if a voltage is applied to the gate electrode, the gate electrode being insulated from the lower electrode contact layer; forming a phase change layer contacting the lower electrode contact layer; and forming an upper electrode contacting the phase change layer.

The lower electrode contact layer may be formed after forming the gate electrode. Forming the lower electrode contact layer after forming the gate electrode may include forming a stacked layer that covers the switching device and includes the gate electrode; exposing the switching device by forming a hole in the stacked layer; forming a spacer insulating layer on sidewalls of the hole; and forming the lower electrode contact layer on the spacer insulating layer. Forming the stacked layer may further include forming a lower insulating layer that covers the switching device; and sequentially forming the gate electrode and an upper insulating layer on the lower insulating layer. The spacer insulating layer may be formed of one selected from the group consisting of a hafnium oxide layer, an aluminum oxide layer, a silicon nitride layer, and a silicon oxide layer, and mixtures thereof.

Forming the lower electrode contact layer after forming the gate electrode may further include forming a stacked layer that covers the switching device and includes the gate electrode; exposing the switching device by forming a hole in the stacked layer; forming a spacer insulating layer on side walls of the hole; covering side surfaces of the spacer insulating layer with the lower electrode contact layer; and forming an insulating layer on the lower electrode contact layer.

According to example embodiments, a method of operating a phase change random access memory (PRAM) may include providing a switching device, a storage node including a phase change layer and a lower electrode contact layer, and a gate electrode configured to temporarily increase an electrical resistance of the lower electrode contact layer if a voltage is applied to the gate electrode, and applying a first voltage to the storage node.

The electrical resistance of the lower electrode contact layer may be increased using the gate electrode while applying the first voltage to the storage node. The first voltage may be a write voltage. The method may further include applying a second voltage, different from the first voltage, to the storage node after applying the first voltage to the storage node. The gate electrode may be formed around the lower electrode contact layer, and the gate electrode may be a unit for applying an electrical field to the lower electrode contact layer to increase an electrical resistance of the lower electrode contact layer.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of a phase-change random access memory (PRAM) according to an example embodiment;

FIG. 2 is a cross-sectional view showing a change in a bottom electrode contact (BEC) layer shown in FIG. 1;

FIG. 3 is a cross-sectional view of the PRAM of FIG. 1 when a switching device is a PN diode;

FIG. 4 is a cross-sectional view of the PRAM of FIG. 1 when the switching device is a field effect transistor (FET);

FIG. 5 is a plan view of a memory array block including a plurality of memory devices shown in FIG. 1 or FIG. 2;

FIGS. 6 through 8 are cross-sectional views illustrating processes of fabricating a PRAM according to an example embodiment;

FIG. 9 is a plan view of a memory array block, which includes a plurality of gate electrodes that is less than the entire memory cells so that each of the gate electrodes is shared by some of the memory cells (two or more memory cells);

FIG. 10 is a plan view of a memory array block, in which gate electrodes and memory cells correspond to each other in one-to-one correspondence;

FIG. 11 is a circuit diagram showing a connecting relation between a first selection line, a second selection line, a transistor used to select a gate electrode that corresponds to the selected memory cell in one-to-one correspondence, and the gate electrode; and

FIG. 12 is a timing flowchart showing a change in voltages applied to a word line, a bit line, and a gate line in writing and reading operations when the switching device of the PRAM is a PN diode.

### DETAILED DESCRIPTION OF EXAMPLE EMBODIMENTS

Reference will now be made in detail to example embodiments, examples of which are illustrated in the accompanying drawings, wherein like reference numerals refer to the like elements throughout. In this regard, example embodiments may have different forms and should not be construed as being limited to the descriptions set forth herein. Accordingly, example embodiments are merely described below, by referring to the figures, to explain aspects of the present description.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, example embodiments will be explained in detail with reference to the accompanying drawings.

A phase change random access memory (PRAM) (hereinafter, referred to as a memory device) according to an example embodiment will be described as follows.

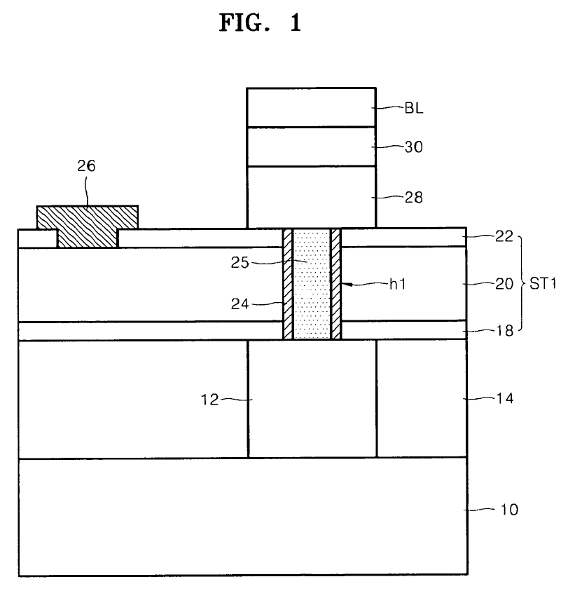

Referring to FIG. 1, a switching device 12 is disposed on a substrate 10. The substrate 10 may include a P-type or an N-type semiconductor substrate, and may include a plurality of layers. The switching device 12 may be a PN diode or a field effect transistor (FET), which will be described in more detail later. An interlayer dielectric 14 surrounding the switching device 12 is formed on the substrate 10. A stacked layer ST1 is disposed on the interlayer dielectric 14. The stacked layer ST1 includes a lower insulating layer 18, a gate electrode 20, and an upper insulating layer 22, which are sequentially stacked. The lower insulating layer 18 may be a metal oxide layer, e.g., a hafnium oxide (HfO) layer, an aluminum oxide (AlO) layer, a silicon nitride layer (SiN), or a silicon oxide layer (SiO).

The gate electrode 20 may be a unit for increasing an electrical resistance of a lower electrode contact plug 25 (or lower electrode contact layer) when data is recorded, e.g., when a phase of a phase change layer 28 is changed from a crystallized status to an amorphous status (reset programming). When a voltage is applied to the gate electrode 20 during the reset programming, an electrical field is applied from the gate electrode 20 to the lower electrode contact plug 25. When the electrical current flows on the lower electrode contact plug 25, the electrical resistance of the lower electrode contact plug 25 becomes higher than when the electrical field is not applied to the lower electrode contact plug 25.

Therefore, the gate electrode 20 may be a unit for applying an electrical field to the lower electrode contact plug 25 in order to increase the electrical resistance of the lower electrode contact plug 25. The lower electrode contact plug 25 may be formed as a pole, for example, a cylinder, a non-cylindrical pole, or a polygonal pole. The gate electrode 20 may be a conductive material, a semiconductor material, metal, or a metal nitride material. For example, the gate electrode 20 may be a conductive material having a resistivity of about 1E-6 Ωcm to about 10 Ωcm. In addition, the gate electrode 20 may be a semiconductor layer including silicon, a metal layer, or a metal nitride layer. The upper insulating layer 22 may be the same as the lower insulating layer 18.

In addition, a hole h1 exposing a part of the switching device 12 is formed in the stacked layer ST1. A sidewall of the hole h1 is covered with a spacer insulating layer 24. The spacer insulating layer 24 may be formed to a thickness of about 1 nm to about 100 nm. The spacer insulating layer 24 may be formed of the same material as that of the lower insulating layer 18. An inner space of the hole h1 is filled with the lower electrode contact plug 25. The switching device 12 and the phase change layer 28 are connected to each other via the lower electrode contact plug 25. The lower electrode contact plug 25 is surrounded by the gate electrode 20 with the spacer insulating layer 24 between them. A pad layer (not shown) may be further disposed between the lower electrode contact plug 25 and the switching device 12.

The lower electrode contact plug 25 may be formed of a material, an electrical resistance of which increases in an electrical field, for example, metal, an alloy, a metal nitride material, or a metal oxide material. In particular, the lower electrode contact plug 25 may be formed of a semiconductor material having a relatively large difference between the electrical resistances when the material is in or out of the electrical field. The lower electrode contact plug 25 may be formed of a semiconductor material having an electrical resistance that increases in the electrical field.

On the upper insulating layer 22, the phase change layer 28 and an upper electrode 30 are sequentially stacked. The phase change layer 28 covers upper surfaces of the lower electrode contact plug 25 and the spacer insulating layer 24. An upper surface of the upper electrode 30 contact a bit line (BL). The phase change layer 28, the lower electrode contact plug 25, and the upper electrode 30 may form a storage node. The phase change layer 28 may be an In—Ge—Sb—Te layer. Furthermore, the phase change layer 28 may be one of a Ge—Sb—Te layer, As—Sb—Te layer, As—Ge—Sb—Te layer, Sn—Sb—Te layer, [(Group VA element)-(Sb or Bi)—Te] layer, [(Group VIA element)-(Sb or Bi)—Te] layer, [(Group VA element)-Sb—Se] layer, and [(Group VIA element)-Sb—Se] layer. Furthermore, the phase change layer 28 may include indium (In). For example, the phase change layer 28 may be one of an In—Sb layer, In—Sb—Te layer, and In—Te layer. Furthermore, the phase change layer 28 may be a layer doped with nitrogen or carbon, e.g., a Te—Ag—Ge—Sb layer or Ge—Sb layer.

When an electrical current is supplied to the lower electrode contact plug 25, Joule heat generates from the lower electrode contact plug 25. A phase of the phase change layer 28 is changed from a crystallized status to an amorphous status, or from the amorphous status to the crystallized status due to the above heat. When the electrical current is a reset current, the phase change layer 28 is changed from the crystallized status to the amorphous status.

As described above, when the lower electrode contact plug 25 is in the electrical field, the electrical resistance of the lower electrode contact plug 25 increases. Therefore, a reset current to change the phase of the phase change layer 28 when the lower electrode contact plug 25 is in the electrical field may be smaller than a reset current to change the phase of the phase change layer 28 when the lower electrode contact plug 25 is not in the electrical field.

In addition, referring to FIG. 1, a gate selection line 26 penetrates through the upper insulating layer 22 and contacts the gate electrode 20. The gate selection line 26 is connected to an electrical power. A voltage is applied from the power to the gate electrode 20 through the gate selection line 26. An end portion of the gate selection line 26 contacts the gate electrode 20. The gate selection line 26 extends over the upper insulating layer 22. The other end portion of the gate selection line 26 may be connected to the power directly or indirectly. The gate selection line 26 is separated from the phase change layer 28, the upper electrode 30, and the bit line BL.

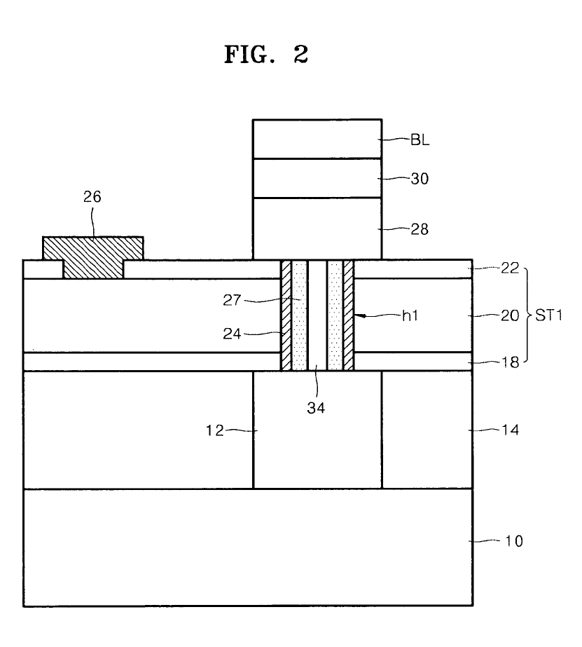

On the other hand, the upper insulating layer 22 around the phase change layer 28 may be surrounded by an insulating layer (not shown). The insulating layer may have the same height as that of the upper surface of the upper electrode 30. The gate selection line 26 may be covered with an insulating layer. However, the gate selection line 26 may be disposed on the insulating layer, and penetrates through the insulating layer and the upper insulating layer 22 to contact the gate electrode 20. The above structure may be applied to the example shown in FIG. 2.

FIG. 2 shows a lower electrode contact plug formed as a cylinder. Referring to FIG. 2, a side wall of the hole h1 that penetrates through the stacked layer ST1 to expose a part of the switching device 12 is covered by the spacer insulating layer 24. The hole h1 may be a circle or non-circle in plane view. When the hole h1 is the non-circle, the hole h1 may be an oval, a rectangle, a triangle, or other polygon. A side wall of the spacer insulating layer 24 is covered with a lower electrode contact layer 27 of a predetermined or given thickness. The lower electrode contact layer 27 may be formed of the same material as that of the lower electrode contact plug 25 shown in FIG. 1. An inner space of the lower electrode contact layer 27 in the hole h1 is filled with an insulating plug 34. Other structures of the memory device may be the same as those of FIG. 1.

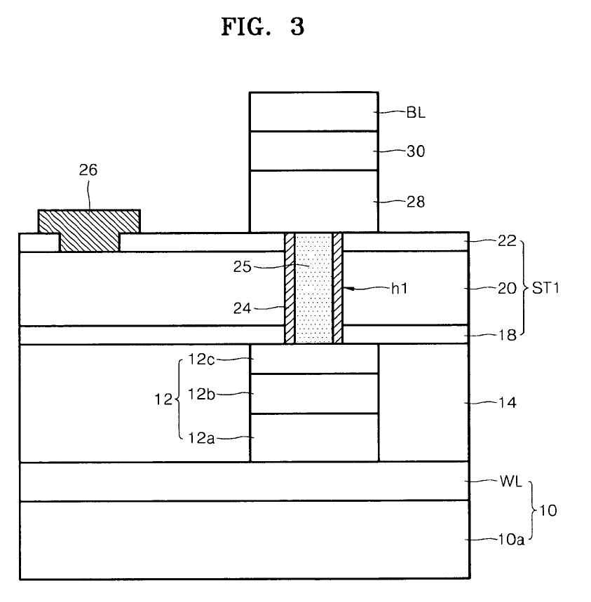

FIG. 3 shows the memory device, in which the switching device 12 is a PN diode. Referring to FIG. 3, the substrate 10 includes a semiconductor substrate 10a and a conductive line WL formed on the semiconductor substrate 10a. The conductive line WL may be a word line. The switching device 12 formed on the conductive line WL may include a first semiconductor layer 12a, a second semiconductor layer 12b, and a conductive layer 12c that are sequentially stacked. The first semiconductor layer 12a may be an N-type semiconductor layer, for example, N− semiconductor layer. The second semiconductor layer 12b may be a P-type semiconductor layer, for example, P+ semiconductor layer. Impurities doped on the first and second semiconductor layers 12a and 12b may have opposite polarities of each other. Therefore, the first semiconductor layer 12a may be the P type semiconductor layer, and the second semiconductor layer 12b may be the N type semiconductor layer. The first and second semiconductor layers 12a and 12b may form a PN diode.

Thus, any kind of material that may form the semiconductor diode may be used to form the first and second semiconductor layers 12a and 12b. The conductive layer 12c is an ohmic contact layer for reducing a contact resistance between the second semiconductor layer 12b and the lower electrode contact plug 25. When the contact resistance between the second semiconductor layer 12b and the lower electrode contact plug 25 is too small to affect the operations of the memory device, the conductive layer 12c may not be formed. In FIG. 3, the hole h1 penetrating the stacked layer ST1 may have the same structure as the hole h1 shown in FIG. 2.

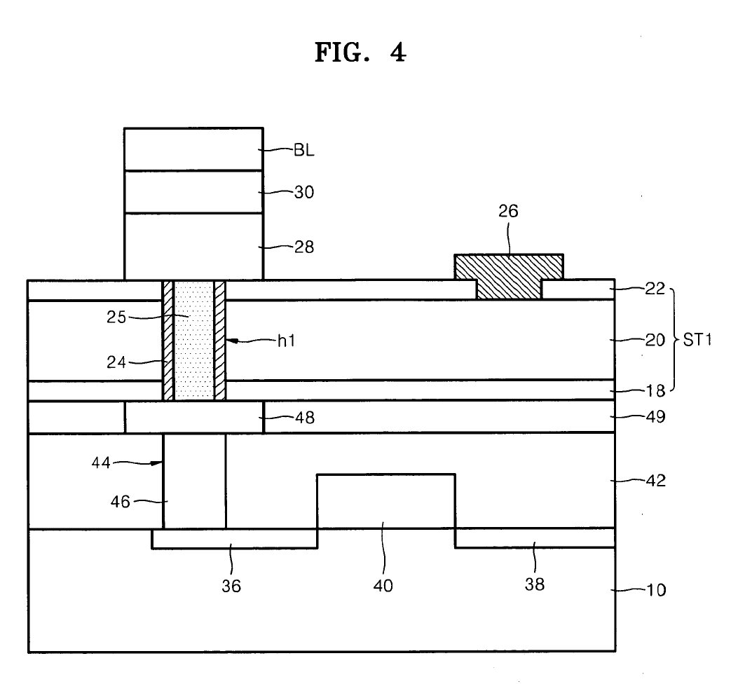

FIG. 4 shows a memory device, in which the switching device 12 is a field effect transistor (FET). Referring to FIG. 4, a gate 40 is formed on the substrate 10. The gate 40 may function as a word line. A first impurity region 36 and a second impurity region 38 are formed in the substrate 10 on both sides of the gate 40. The substrate 10 may be a semiconductor substrate doped with P-type or N-type impurities. The first and second impurity regions 36 and 38 are doped with impurities having the polarity that is opposite to the impurites doped on the substrate 10. One of the first and second impurity regions 36 and 38 may be a source region, and the other may be a drain region. The substrate 10 including the first and second impurity regions 36 and 38 and the gate 40 may form a transistor.

An interlayer dielectric 42 that covers the transistor and has an even surface is formed on the substrate 10. A contact hole 44 exposing the first impurity region 36 is formed in the interlayer dielectric 42. The contact hole 44 is filled with a conductive plug 46. A conductive pad layer 48 covering the conductive plug 46 is formed on the interlayer dielectric 42. An upper surface of the interlayer dielectric 42 around the conductive pad layer 48 is covered with an insulating layer 49. An upper surface of the insulating layer 49 and an upper surface of the conductive pad layer 48 are at the same height.

The stacked layer ST1 is formed on the insulating layer 49 and the conductive pad layer 48. At this time, the hole h1 penetrating the stacked layer ST1 is located on the conductive pad layer 48. Other configurations of the memory device may be the same as those of FIG. 1 or FIG. 2. The gate selection line 26 may be disposed on a right side of the phase change layer 28. In this case, the gate selection line 26 may be formed on an insulating layer around the phase change layer 28 and the upper electrode 30 to contact the gate electrode 20. A memory array block including a plurality of memory devices of FIG. 1 may be configured.

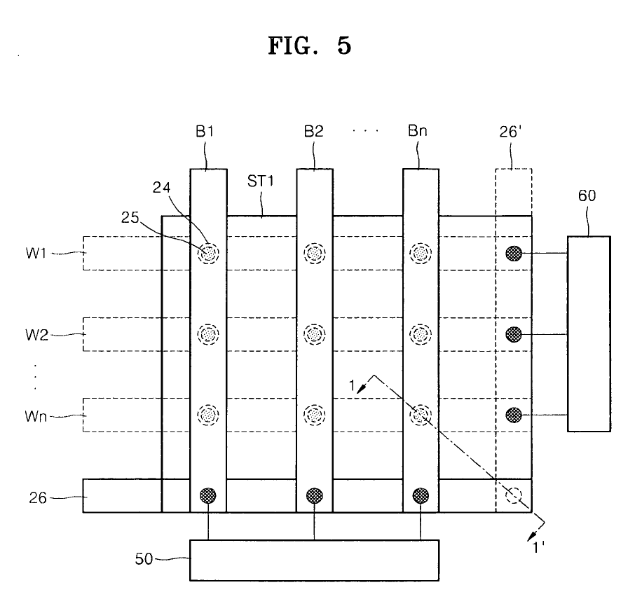

FIG. 5 shows an example embodiment of arranging elements in the memory array block. The phase change layer and the switching device are not shown in FIG. 5 for convenience. The example embodiment of the memory array block may be applied to the memory array block including the memory devices of FIG. 2. FIG. 1 shows a part of the memory array block of FIG. 5 taken along line 1-1′.

Referring to FIG. 5, lower electrode contact plugs 25 are formed on regions where word lines W1-Wn and bit lines B1-Bn cross each other. The lower electrode contact plugs 25 are surrounded by the spacer insulating layers 24. The gate selection line 26 (hereinafter, referred to as first gate selection line) is disposed to be parallel with the word lines W1-Wn. A second gate selection line 26′ may be further disposed to be parallel with the bit lines B1-Bn. The second gate selection line 26′ may share a contact region with the first gate selection line 26. The first and second gate selection lines 26 and 26′ may be separated from each other, and may not share the contact regions. When both of the first and second gate selection lines 26 and 26′ are formed in the memory array block, a voltage may be applied to the gate 20 (refer to FIG. 1) of the stacked layer ST1 through one of the first and second gate selection lines 26 and 26′.

On the other hand, when the first and second gate selection lines 26 and 26′ are formed in the memory array block, the first and second gate selection lines 26 and 26′ may be separated from each other in a vertical direction. For example, the first gate selection line 26 may be disposed on the upper insulating layer 22 of the stacked layer ST1 as shown in FIG. 1. In addition, the second gate selection line 26′ may be formed on an insulating layer (not shown) that surrounds the phase change layer 28 and the upper electrode 30 and covers the first gate selection line 26. In this case, the first and second gate contact lines 26 and 26′ may share the contact to the gate electrode 20, however, the first and second gate contact lines 26 and 26′ may contact the gate electrode 20 at different positions from each other.

A bit line B1-Bn is selected by a bit line selection circuit 50, and a word line W1-Wn is selected by a word line selection circuit 60. Therefore, a memory cell, on which data will be recorded or from which the data is read, is selected by the bit line selection circuit 50 and the word line selection circuit 60. In the memory array block of FIG. 5, each of the word lines W1-Wn may be the conductive line WL shown in FIG. 3 or the gate 40 shown in FIG. 4. The number of memory cells included in the memory array block of FIG. 5 may be about 2 to about 106. A memory apparatus or an electronic device may include a plurality of the memory array blocks.

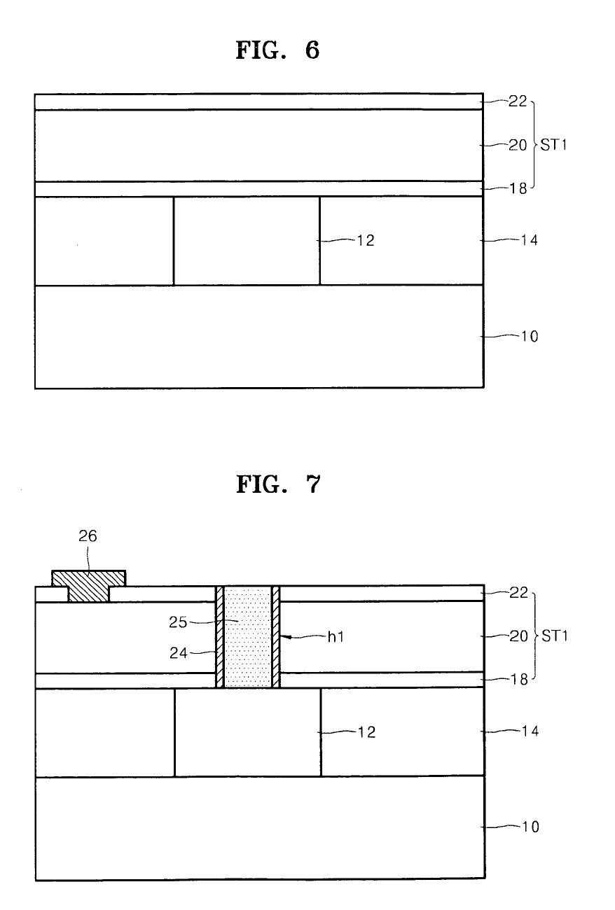

Processes of fabricating the memory device according to example embodiments will be described with reference to FIGS. 6 through 8. Referring to FIG. 6, the switching device 12 is formed on the substrate 10. The substrate 10 may be a semiconductor substrate. In addition, the substrate 10 may include a semiconductor substrate and a conductive line that are sequentially stacked. The switching device 12 may be the PN diode as shown in FIG. 3, or the FET as shown in FIG. 4. The substrate 10 around the switching device 12 is covered with the interlayer dielectric 14. The interlayer dielectric 14 may be formed by forming an insulating layer on the substrate 10 to cover the switching device 12, and by planarizing an entire surface of the insulating layer until the switching device 12 is exposed. The planarization may be performed using a chemical mechanical polishing process or another polishing process.

The lower insulating layer 18 covering the switching device 12, the gate electrode 20, and the upper insulating layer 22 are sequentially stacked on the interlayer dielectric 14 to form the stacked layer ST1. The lower insulating layer 18, the upper insulating layer 22, and the gate electrode 20 may be formed of the material described with reference to FIG. 1.

Referring to FIG. 7, the hole h1 is formed in the stacked layer ST1. The spacer insulating layer 24 is formed on the side wall of the hole h1. The spacer insulating layer 24 may be formed to a thickness of about 1 nm to about 100 nm. The spacer insulating layer 24 may be formed by forming a thin insulating layer (not shown) on an upper surface of the stacked layer ST1 and by anisotropic etching of the thin insulating layer. Due to the anisotropic etching, the thin insulating layer is removed except for a portion covering the side wall of the hole h1. The space inside the spacer insulating layer 24 in the hole h1 is filled with the lower electrode contact plug 25. The lower electrode contact plug 25 may be formed of the material described with reference to FIG. 1.

After the hole h1 is filled with the lower electrode plug 25 as described above, a part of the upper insulating layer 22 is removed to expose a part of the gate electrode 20. The first gate selection line 26 that contacts the exposed part of the gate electrode 20 may be formed on the upper insulating layer 22. During the above reset programming, a voltage is applied to the gate electrode 20 through the first gate selection line 26. The second gate selection line 26′ shown in FIG. 5 may be further formed on the upper insulating layer 22 in addition to the first gate selection line 26. The first gate selection line 26 and the second gate selection line 26′ may share the contact region to the gate electrode 20, however, may have contact regions independently.

The memory device contacting the first gate selection line 26 may be one of the memory devices included in the memory array block of FIG. 5. The gate electrode 20 is formed as a plate so as to be shared by the entire memory devices included in the memory array block. Therefore, other memory devices except for one memory device that contacts the first gate selection line 26 may not contact the first gate selection line 26. That is, the gate electrode 20 may be contacted on two or more regions in the memory array block shown in FIG. 5, however, since the gate electrode 20 are shared by the memory devices included in the memory array block, the gate electrode 20 may have only one contact point.

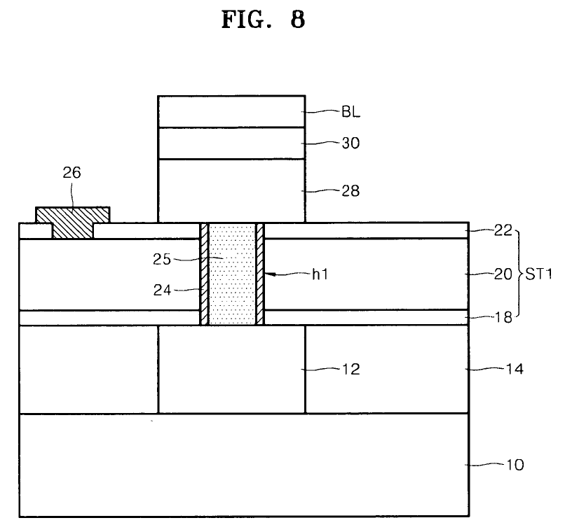

Referring to FIG. 8, the phase change layer 28 and the upper electrode 30 are sequentially stacked on the upper insulating layer 22 in the stacked layer ST1. After that, a bit line BL is formed on the upper electrode 30. Patterns of the phase change layer 28 and the upper electrode 30 shown in FIG. 8 may be formed by sequentially stacking the phase change layer 28 covering the first gate selection line 26 and the upper electrode 30 on the upper insulating layer 22, and patterning the stacked phase change layer 28 and the upper electrode 30 using a mask having the pattern of FIG. 8.

In the above fabrication processes, the lower electrode contact layer 25 may be formed earlier than the gate electrode 20. In more detail, the lower electrode contact layer 25 and the spacer insulating layer 24 covering the lower electrode contact layer 25 are formed, and the lower insulating layer 18, the gate electrode 20, and the upper insulating layer 22 may be sequentially formed. In the above processes, the spacer insulating layer 24 covering the upper surface of the lower electrode contact layer 25 is removed.

On the other hand, when the switching device 12 is the PN diode shown in FIG. 3, in the above fabrication processes, a region, on which the switching device 12 will be formed, may be ensured in advance by forming the interlayer dielectric 14 on the substrate 10 and forming the hole in the interlayer dielectric 14. After that, the elements of the PN diode shown in FIG. 3 are sequentially stacked in the hole to form the PN diode.

On the other hand, during formation of the memory array block shown in FIG. 5 using the above described processes, the gate electrode 20 may be divided into a plurality of gate electrodes. In this case, one gate electrode 20 is not shared by all of the memory cells, but a plurality of gate electrodes 20 are shared by all of the memory cells. Therefore, each of the gate electrodes 20 is shared by some of the memory cells.

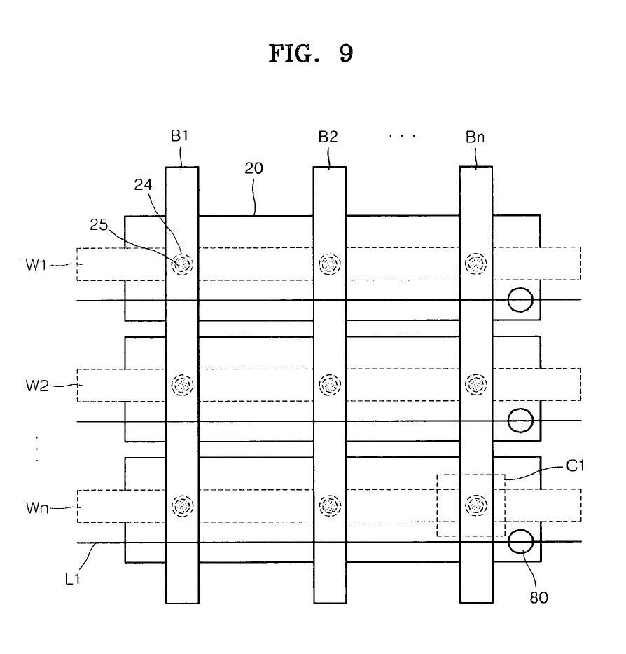

In FIG. 9, the separated gate electrodes 20 are shown instead of the stacked layer ST1 for convenience. Referring to FIG. 9, the number of the gate electrodes 20 is equal to the number of word lines W1-Wn. The gate electrodes 20 are formed in parallel with the word lines W1-Wn. Each of the gate electrodes 20 is shared by the memory cells that are connected to one word line. In order to apply voltage to the gate electrodes 20, selection lines L1 of the same number as that of the word lines W1-Wn are formed. Reference numeral 80 denotes a contact between the selection line L1 and the gate electrode 20. In addition, during formation of the gate electrodes 20, the gate electrode 20 may be divided to correspond to the memory cells in one-to-one correspondence.

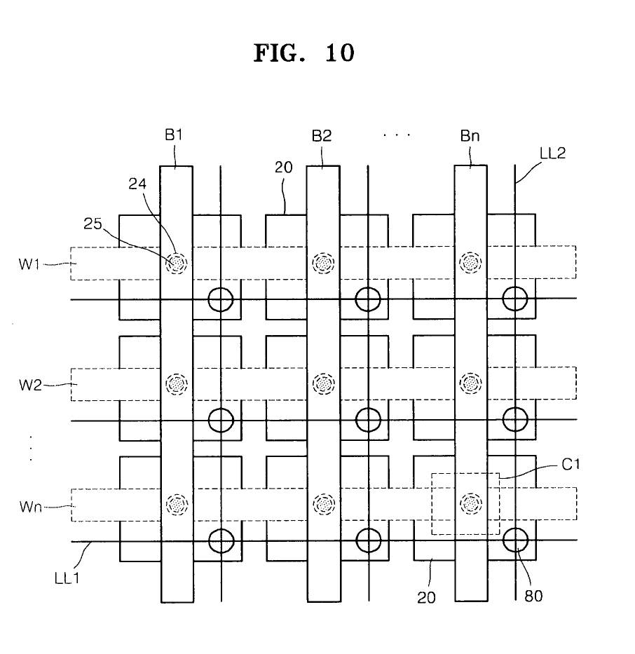

Referring to FIG. 10, the memory cells C1 and the gate electrodes 20 correspond to each other in one-to-one correspondence. In addition, each of the gate electrodes 20 is independent from the other. First selection lines LL1 of the same number as that of the word lines W1-Wn are formed, and second selection lines LL2 of the same number as that of the bit lines B1-Bn are formed. An n-th word line Wn and an n-th bit line Bn are selected to select a memory cell C1 formed on a region where the n-th word line Wn and the n-th bit line Bn cross each other, and then, the data is recorded on the selected memory cell C1.

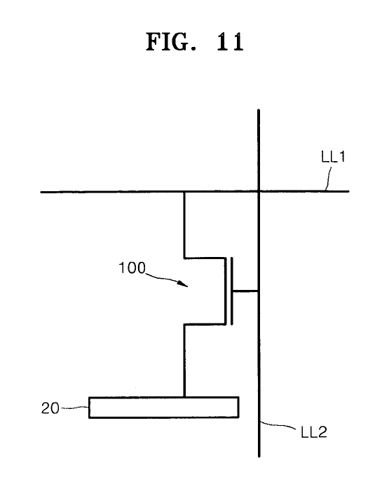

A first selection line LL1 that is parallel with the n-th word line Wn and passes over the selected memory cell C1 and a second selection line LL2 that is parallel with the first bit line B1 and passes over the selected memory cell C1 are selected to apply a voltage to the gate electrode 20 shared by the selected memory cell C1. The first selection line LL1 and the second selection line LL2 may be connected to the gate electrode 20 through the transistor. The transistor is turned on by the voltage applied through one of the first and second selection lines LL1 and LL2. A voltage is applied to the gate electrode 20 through the other of the first and second selection lines LL1 and LL2. Connecting relations between the first and second selection lines LL1 and LL2, the gate electrode 20, and the transistor are shown in FIG. 11.

In FIG. 11, the second selection line LL2 is connected to a gate of a transistor 100, a first selection line LL1 is connected to one of the two terminals of the transistor 100, and the gate electrode 20 is connected to the other terminal. Processes of operating the memory device according to one or more example embodiments will be described as follows. The operation processes will be described with reference FIG. 1, or FIGS. 2 and 5. A bit line and a word line are selected using the bit line selection circuit 50 and the word line selection circuit 60. For convenience sake, it is assumed that the n-th word line Wn and the n-th bit line Bn are selected. The process of writing the data in the selected memory cell C1 may be a process of changing the phase of the phase change layer 28 in the selected memory cell C1 to the amorphous status.

The above processes may be performed as follows. In more detail, a voltage is applied to the gate electrode 20 through the first gate selection line 26. The second gate selection line 26′ may be used instead of the first gate selection line 26, if necessary. The voltage applied to the gate electrode 20 may be about 0.1V to about 100V. An electrical field is generated from the gate electrode 20 due to the voltage applied to the gate electrode 20. Therefore, the lower electrode contact plug 25 surrounded by the gate electrode 20 is in the electrical field. As described above, a write voltage is applied to the selected memory cell C1 that is in the electrical field through the n-th bit line Bn and the n-th word line Wn. The write voltage and the voltage applied to the gate electrode 20 may be performed simultaneously. A reset current flows to the phase change layer 28 through the lower electrode contact plug 25 due to the write voltage, and the phase of the phase change layer 28 is changed from the crystallized status to the amorphous status due to the heat generated from the lower electrode contact plug 25 (reset program).

The electrical resistance of the lower electrode contact plug 25 in the electrical field increases. Therefore, the reset current supplied to the lower electrode contact plug 25 in the electrical field may be smaller than a reset current (reference reset current) for changing the phase of the phase changing layer 28 to the amorphous status when there is no electrical field.

As described above, when the electrical field exists during the reset programming, the electrical resistance of the lower electrode contact plug 25 increases even when the reset current is less than the reference reset current, and thus, the lower electrode contact plug 25 may generate heat that is the same as the heat generated when there is no electrical field. Consequently, the reset programming may be performed with the reset current that is less than the reference reset current, and thus, the power consumption may be reduced.

When the writing of data onto the phase change layer 28 is finished, the voltage applied to the gate electrode 20 is turned off. Then, the data writing onto the selected memory cell C1 is finished. When the phase of the phase change layer 28 is changed to the amorphous status, the data 1 is recorded in the phase change layer 28.

After recording the data 1, a voltage (second voltage) that is different from the write voltage may be applied to the phase change layer 28. The second voltage may be a read voltage for reading the data 1, or may be a write voltage for replacing the data 1 with the data 0.

If the above write voltage is for changing the phase of the phase change layer 28 from the amorphous status to the crystallized status, the voltage is not applied to the gate electrode 20. Therefore, the electrical field is not generated. When the phase of the phase change layer 28 is the crystallized status, the data 0 is recorded in the phase change layer 28. When the phase of the phase change layer 28 is in an initially crystallized status, the write voltage for recording data 0 may not be applied. The data 1 and the data 0 may be set reversely according to the phase of the phase change layer 28.

As described above, according to the memory device of one or more example embodiments, the reset current is not reduced by changing the specification of the phase change layer 28, e.g., a length or a width of the phase change layer 28 in the writing operation, but the electrical field is applied from outside of the lower electrode contact plug 25 to the lower electrode contact plug 25 when the reset current is supplied in order to increase the electrical resistance of the lower electrode contact plug 25 temporarily. Therefore, the reset current is reduced, however, the set resistance does not increase.

On the other hand, because the resistance of the path, on which currents relating to operations, e.g., a write current or a read current flow, is not permanently increased by changing the specification or material forming the path but the electrical resistance of the lower electrode contact plug 25 is temporarily increased when the reset current is supplied, only the reset current is reduced and the set resistance is not increased.

Therefore, the reset resistance that is the resistance when the data 1 is recorded and the set resistance that is the resistance when the data 0 is recorded may be distinguished clearly from each other, and thus, the data may be read accurately since a sufficient reading marging is ensured.

On the other hand, when the switching device 12 connected to the lower electrode contact plug 25 is the transistor as shown in FIG. 4, the gate 40 of the transistor may function as the word line. Therefore, when the switching device 12 is the transistor and the lower electrode contact plug 25 is connected to the first impurity region 36 of the transistor, a voltage is applied between the bit line and the second impurity region 38 of the transistor in the write operation to apply the write voltage to the phase change layer 28. Processes of applying the electrical field to the lower electrode contact plug 25 are the same as described above.

A read voltage is applied between the n-th bit line Bn and the n-th word line Wn in the selected memory cell C1. The read voltage may be lower than a threshold voltage that may affect the phase of the phase change layer 28. Therefore, even when the read voltage is applied, the data recorded in the phase change layer 28 is not affected. After applying the read voltage to the phase change layer 28 to measure the current, the measured current is compared with a reference current. When the measured current is greater than the reference current as a result of comparison, the phase change layer 28 is in the crystallized status, and thus the measured current may denote that the data 0 is read. On the other hand, when the measured current is less than the reference current, the phase change layer 28 is in the amorphous status, and thus the measured current may denote that the data 1 is read.

After the reading operation, a write operation for writing new data into the memory cell, from which the data is read, may be performed. The writing operation may be the same as the above described operation.

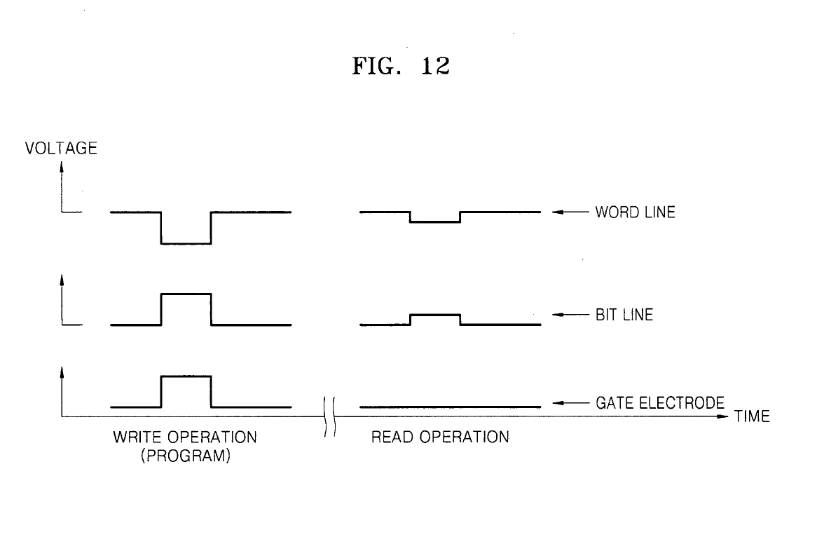

FIG. 12 shows changes in voltages applied to the word line, the bit line, and the gate electrode in the writing and reading operations, when the switching device 12 of the memory device according to an example embodiment is the PN didode.

Referring to FIG. 12, the voltage applied to the word line before the writing operation (program) is maintained at a high status, and the voltage applied to the bit line is maintained at a low status. As the writing operation starts, the voltage applied to the word line is changed to the low status, and the voltage applied to the bit line is changed to the high status. The reset current flows in the storage node including the phase change layer and the lower electrode contact layer, and at the same time, a voltage is applied to the gate electrode.

On the other hand, in the reading operation, the magnitudes of voltages applied to the word line and the bit line are reduced, and the voltage is not applied to the gate electrode. Therefore, the resistance of the lower electrode contact layer is low, the same as that before the electrical field is applied to the lower electrode contact layer. Therefore, the set resistance is not increased, and a reduction in margin caused by the increase of the ratio between the set resistance/reset resistance may be prevented or reduced.

It should be understood that example embodiments described therein should be considered in a descriptive sense only and not for purposes of limitation. Descriptions of features or aspects within each embodiment should typically be considered as available for other similar features or aspects in other example embodiments.

What is claimed is:

1. A phase change random access memory (PRAM) comprising:
a switching device;
a storage node including a phase change layer and a lower electrode contact layer; and
a gate electrode configured to temporarily increase an electrical resistance of the lower electrode contact layer if a voltage is applied to the gate electrode.

2. The PRAM of claim 1, wherein the switching device is a diode or a transistor.

3. The PRAM of claim 1, further comprising:
a spacer insulating layer disposed between the lower electrode contact layer and the gate electrode.

4. The PRAM of claim 1, wherein the gate electrode is disposed around the lower electrode contact layer, and the gate electrode is a unit for applying an electrical field to the lower electrode contact layer in a reset programming.

5. The PRAM of claim 1, further comprising:
at least one additional switching device and at least one additional storage node including at least one phase change layer and at least one lower electrode contact layer,
wherein the gate electrode corresponds to the at least one lower electrode contact layer.

6. The PRAM of claim 1, wherein the lower electrode contact layer has a shape of a pole or a cylinder.

7. The PRAM of claim 1, wherein the lower electrode contact layer is a layer formed of a material that changes an electrical resistance in the electrical field.
